(19) United States
(12) Patent Application Publication
(10) Pub. No.: US 2011/0027699 A1
(43) Pub. Date: Feb. 3, 2011

(54) REDUCING ION MIGRATION OF ABSORBER MATERIALS OF LITHOGRAPHY MASKS BY CHROMIUM PASSIVATION

(76) Inventors: Anna Tchikoulaeva, Dresden (DE); Eugen Foca, Radeseul (DE); Pavel Nesladek, Dresden (DE)

Correspondence Address: GLOBALFOUNDRIES INC.;c/o Williams, Morgan & Amerson, 10333 Richmond , Suite 1100, Houston, TX, 77042, US

(21) Appl. No.: 12/835,212

(22) Filed: Jul. 13, 2010

(30) Foreign Application Priority Data
Jul. 31, 2009 (DE) 10 2009 035 432.8
Nov. 19, 2009 (DE) 10 2009 046 878.1

(51) Int. Cl. G03F 1/00

(52) U.S. Cl. 430/5

(57) ABSTRACT

The deterioration of photomasks caused by chromium migration in COG masks may be reduced or suppressed by avoiding substantially pure chromium materials or encapsulating these materials, since the chromium layer has been identified as a major contributor to the chromium diffusion.

### BACKGROUND OF THE INVENTION

1. Field of the Invention

Generally, the subject matter disclosed herein relates to microelectronics, and, more particularly, to forming advanced lithography masks based on chromium and its compounds.

2. Description of the Related Art

The fabrication of microstructures, such as integrated circuits, requires tiny regions of precisely controlled size to be formed in one or more material layers of an appropriate substrate, such as a silicon substrate, a silicon-on-insulator (SOI) substrate or other suitable carrier materials. These tiny regions of precisely controlled size are typically defined by patterning the material layer(s) by applying lithography, etch, implantation, deposition processes and the like, wherein typically, at least in a certain stage of the patterning process, a mask layer may be formed over the material layer(s) to be treated to define these tiny regions. Generally, a mask layer may consist of or may be formed by means of a layer of photoresist that is patterned by a lithographic process, typically a photolithography process. During the photolithography process, the resist may be spin-coated onto the substrate surface and then selectively exposed to radiation, typically ultraviolet radiation, through a corresponding lithography mask, such as a reticle, thereby imaging the reticle pattern into the resist layer to form a latent image therein. After developing the photoresist, depending on the type of resist, positive resist or negative resist, the exposed portions or the non-exposed portions are removed to form the required pattern in the layer of photoresist. Based on this resist pattern, actual device patterns may be formed by further manufacturing processes, such as etch, implantation, anneal processes, and the like. Since the dimensions of the patterns in sophisticated integrated microstructure devices are steadily decreasing, the equipment used for patterning device features have to meet very stringent requirements with regard to resolution and overlay accuracy of the involved fabrication processes. In this respect, resolution is considered as a measure for specifying the consistent ability to print minimum size images under conditions of predefined manufacturing variations. One important factor in improving the resolution is the lithographic process, in which patterns contained in the photo mask or reticle are optically transferred to the substrate via an optical imaging system. Therefore, great efforts are made to steadily improve optical properties of the lithographic system, such as numerical aperture, depth of focus and wavelength of the light source used.

The resolution of the optical patterning process may, therefore, significantly depend on the imaging capability of the equipment used, the photoresist materials for the specified exposure wavelength and the target critical dimensions of the device features to be formed in the device level under consideration. For example, gate electrodes of field effect transistors, which represent an important component of modern logic devices, may be 40 nm and even less for currently produced devices, with significantly reduced dimensions for device generations that are currently under development. Similarly, the line width of metal lines provided in the plurality of wiring levels or metallization layers may also have to be adapted to the reduced feature sizes in the device layer in order to account for the increased packing density. Consequently, the actual feature dimensions may be well below the wavelength of currently used light sources provided in current lithography systems. For example, currently, in critical lithography steps, an exposure wavelength of 193 nm may be used, which, therefore, may require complex techniques for finally obtaining resist features having dimensions well below the exposure wavelength. Thus, highly non-linear processes are typically used to obtain dimensions below the optical resolution. For example, extremely non-linear photoresist materials may be used, in which a desired photochemical reaction may be initiated on the basis of a well-defined threshold so that weakly exposed areas may not substantially change at all, while areas having exceeded the threshold may exhibit a significant variation of their chemical stability with respect to a subsequent development process. The usage of highly non-linear imaging processes may significantly extend the capability for enhancing the resolution for available lithography tools and resist materials.

Due to the complex interaction between the imaging system, the resist material and the corresponding pattern provided on the reticle, even for highly sophisticated imaging techniques, which may possibly include optical proximity corrections (OPC), phase shifting masks and the like, the consistent printing of latent images, that is, of exposed resist portions which may be reliably removed or maintained, depending on the type of resist used, may also significantly depend on the specific characteristics of the respective features to be imaged. Furthermore, the respective process parameters in such a highly critical exposure process may have to be controlled to remain within extremely tight process tolerances, which may contribute to an increasing number of non-acceptable substrates, especially as highly scaled semiconductor devices are considered. Due to the nature of the lithography process, the corresponding process output may be monitored by respective inspection techniques in order to identify non-acceptable substrates, which may then be marked for reworking, that is, for removing the exposed resist layer and preparing the respective substrates for a further lithography cycle. However, lithography processes for complex integrated circuits may represent one of the most dominant cost factors of the entire process sequence, thereby requiring a highly efficient lithography strategy to maintain the number of substrates to be reworked as low as possible. Consequently, the situation during the formation of sophisticated integrated circuits may increasingly become critical with respect to throughput.

An important aspect in reducing failure associated with advanced lithography processes may be related to the photomasks or reticles that are used for forming the latent images in the resist layer of the substrates. In modern lithography techniques, typically, an exposure field may be repeatedly imaged into the resist layer, wherein the exposure field may contain one or more die areas, the image of which is represented by the specific photomask or reticle. In this context, a reticle may be understood as a photomask in which the image pattern is provided in a magnified form and is then projected onto the substrate by means of an appropriate optical projection system. Thus, the same image pattern of the reticle may be projected multiple times onto the same substrate according to a specified exposure recipe, wherein, for each exposure process, the respective exposure parameters, such as exposure dose, depth of focus and the like, may be adjusted within a predetermined process window in order to obtain a required quality of the imaging process for each of the individual exposure fields. Thus, an exposure recipe may be defined by determining an allowable range of parameter values for each of the respective parameters, which may then be adjusted prior to the actual exposure process on the basis of appropriate data, such as an exposure map and the like. Furthermore, prior to each exposure step, an appropriate alignment procedure may be performed to precisely adjust one device layer above the other on the basis of specified process margins. During the entire exposure process, a plurality of defects may be created, which may be associated with any deficiencies or imperfections of the exposure tool, the substrate and the like. In this case, a plurality of defects may be generated, the occurrence of which may be systematic or random and may require respective tests and monitoring strategies. For example, a systematic drift of tool parameters of the exposure tools may be determined on the basis of regular test procedures, while substrate specific defects may be determined on the basis of well-established wafer inspection techniques so as to locate respective defects, such as particles and the like.

Another serious source of defects may be the photomask or reticle itself, due to particles on the reticle, damaged portions and the like. As previously explained, in sophisticated lithography techniques, a plurality of measures have to be implemented in order to increase the overall resolution, wherein, for instance, in many cases, phase shift masks may be used, which comprise portions with an appropriately defined optical length so as to obtain a desired degree of interference with radiation emanating from other portions of the reticle. For example, at an interface between a light-blocking region and a substantially transmissive region of the mask, respective diffraction effects may result in blurred boundaries, even for highly non-linear resist materials. In this case, a certain degree of destructive interference may be introduced, for instance by generating a certain degree of phase shift of, for instance, 180 degrees, while also providing a reduced intensity of the phase shifted fraction of the radiation, which may result in enhanced boundaries in the latent image of the resist between resist areas corresponding to actually non-transmissive and transmissive portions in the photomask. Consequently, for certain types of reticles, a change of the absorption may result in a defect in the corresponding latent image in the resist layer, which may then be repeatedly created in each exposure field. Similarly, any other defects in the reticle may result in repeated defects, which may cause a significant yield loss if the corresponding defects may remain undetected over a certain time period. There are many reasons for failures caused by reticle defects, such as insufficiency of the manufacturing sequence for forming reticles, defects created during reticle transport and reticle handling activities and the like.

For example, two major failure sources are the generation of haze and electrostatic discharge (ESD). Both types of failures will finally lead to a complete mask deterioration and typically have the consequence of requiring the mask to be withdrawn from the production process. While masks becoming hazy can be partially recovered after appropriate cleaning processes in a mask house, ESD failures represent typical damages, which may not be recovered and may make the photomask no longer usable.

Recently, a new form of mask degradation has been identified by Rider and Kalkur, “Experimental quantification of reticle electrostatic damage below the threshold for ESD (Proceedings Paper),” Metrology Inspection and Process Control for Microlithography XXII, edited by Allgair, Sean A; Raymond, Christopher J; Proceedings of the SPIE, Vol. 6922, p. 69221Y-11 (2008), and this failure mechanism has been confirmed by Tchikoulaeva et al., “ACLV degradation: root cause analysis and effective monitoring strategy,” Photomask and Next Generation Lithography Mask Technology XV, edited by Horiochi, Toshiyuki, Proceedings of the SPIE, Vol. 7028, p. 72816-10 (2008). A specific aspect of this degradation mechanism is the so-called chromium migration on the quartz surface of the photomask. The reason why chromium ions tend to leave the bulk material is not quite fully understood. A possible cause is the Ostwald ripening that is a common effect in solid state with a granular nature. Generally, migration of chromium ions will always take place upon minimizing the free energy of the chromium species within the bulk. Assuming that a chromium ion is always “ready” for leaving the bulk material, an external activation force is required to start the migration. Although an exact mechanism is not yet understood, it is assumed that an external electric field may act as activating energy which can result in detectable chromium migration, as will be described with reference to FIG. 1a.

FIG. 1a schematically illustrates a cross-sectional view of a portion of a photomask comprising a transparent substrate material 101, such as quartz glass and the like, above which are formed mask features 102, which represent substantially opaque components with respect to the exposure wavelength to be used in a corresponding lithography process, as explained above. For convenience, a single mask feature is illustrated in FIG. 1a, which is comprised of a patterned layer stack 110 in which material layers including a chromium species are provided. It should be appreciated that chromium may represent well-established materials for forming opaque areas on photomasks due to its absorbing characteristics, the well-established material resources and process tools and the like. In this case, the photomask 100 may also be referred to as a chrome on glass (COG) mask. As discussed above, the layer stack 110 may be patterned on the basis of the corresponding critical dimensions for a specific device layer of a semiconductor device when the feature 102 is projected onto a photosensitive material. In the example shown, the layer stack 110 includes three material layers 111, 112 and 113, each of which comprises a chromium species. The first layer 111 directly formed on the substrate material 101 is a chromium nitride (CrN) with a thickness of approximately 10 nm, followed by the layer 112 in the form of a chromium (Cr) layer having a thickness of several tenths of nanometers. Finally, a chromium oxide material (CrO) is provided as the layer 113 and may typically act as an anti-reflective coating (ARC) material for a specified exposure wavelength. For example, the overall height of the layer stack 110 may be approximately 105 nm and less, wherein an absorbance of the layer stack 110 is adjusted on the basis of the optical characteristics of the layers 111, 112 and 113. During exposure of the photomask 100 by an exposure radiation 103, for instance with a wavelength of 193 nm in currently used exposure tools, photo emission may occur in the feature 102, as indicated by 104, thereby resulting in electron depletion of the feature 102 during illumination in the exposure tool. Consequently, a potential difference may build up with respect to any point of the surface of the substrate 101 provided quantum efficiency is different compared to any point on the substrate 101. Consequently, an electric field 105 may be generated, which in turn may act on chromium ions, as discussed above, thereby creating a current 106, i.e., a directed diffusion of chromium ions, which may finally result in a significant mass displacement. Generally, the generation of the electric field 105 due to the photon bombardment 103 during an exposure process may be one source of energy leading to increased chromium migration, wherein, however, any other mechanism that may result in a charging of the photomask 100 may also result in a moderately high electric field, which may then also contribute to chromium migration. For this reason, this phenomenon may also be referred to as electric field induced migration (EFM). Since the pronounced chromium migration may result in a significant modification of the feature 102, for instance by affecting the optical density and the like, the result of the imaging process may also be strongly influenced by the chromium migration. One consequence is that vias close, lines enlarge leading to higher CD sizes and clears close leading to smaller CD sizes.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides photomask products, photomasks and manufacturing techniques in which the effect of chromium migration may be reduced, thereby contributing to superior lifetime of photomasks, which may thus directly translate into reduced overall production costs. Without intending to restrict the present application to the following explanation, it is assumed that chromium migration is substantially caused by the presence of a chromium layer as a source of chromium ions available for migration under the effect of an external activating force, such as an electric field. Investigations of the inventors seem to indicate that the chromium ions leaving the chromium layer of conventional photomasks may finally be converted into chromium oxide, thereby resulting in a non-acceptable modification of the optical characteristics, which may thus result in premature failure of the photomask. According to the principles disclosed herein, a reduction in chromium migration may be accomplished by substantially eliminating or at least significantly reducing the source for delivering migrating chromium ions and/or preventing undue chromium diffusion and/or reducing the effect of electric fields that may be generated during operating and handling the photomask. In some illustrative aspects disclosed herein, a superior chromium-based material layer stack may be provided as a base material for forming mask features of a photomask, in which a substantially pure chromium layer may be avoided, thereby efficiently reducing a degree of chromium diffusion. In other illustrative aspects, an efficient diffusion barrier may be provided, for instance in the form of a dielectric material, which uptakes the built-in potential, hence reducing the activation energy required for starting chromium migration on the quartz substrate. Additionally, an appropriate material might be used to suppress or significantly reduce the out-diffusion of chromium species from any surface areas, such as sidewalls of mask features. An appropriate diffusion barrier material may be efficiently provided during the patterning of a photomask product comprising an appropriate chromium-based material layer stack, such as a conventionally used chromium nitride/chromium/chromium oxide layer stack.

One illustrative photolithography mask product disclosed herein comprises a transparent substrate and a material layer stack formed on the transparent substrate. The material layer stack comprises a first material layer formed on the substrate and a second material layer formed on the first material layer. Furthermore, the first material layer comprises a chromium-containing compound and the second material layer comprises at least one non-chromium species with a fraction of approximately 20 atomic percent or more. It is to be understood that the fraction of the non-chromium species is to be understood in relation to the overall amount of material species in the second material layer.

One illustrative photolithography mask disclosed herein comprises a transparent substrate and an opaque mask feature formed on the transparent substrate. The opaque mask feature comprises a chromium layer formed above the transparent substrate, wherein the chromium layer has a bottom face and a top face and sidewall faces. Furthermore, the opaque mask feature comprises a sidewall protection feature formed on each of the sidewall faces wherein a composition of the sidewall protection material differs from a composition of the chromium layer.

One illustrative method disclosed herein relates to forming a photolithography mask. The method comprises patterning a material layer stack formed on a transparent substrate to form a mask feature, wherein the material layer stack comprises at least one chromium-containing material layer. Additionally, the method comprises passivating the mask feature to reduce chromium diffusion.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a conventional chromium-based photomask when exposed to diffusion, which may cause a significant electron depletion, leading to generation of built-in potential, which is believed to contribute to a significant chromium diffusion and thus variation of the optical characteristics;

FIGS. 1b-1c schematically illustrate cross-sectional views of a conventional photomask during various stages of a significant chromium diffusion, wherein it is assumed according to the principles disclosed herein, but not limited to, that the major source for feeding the chromium migration represents the chromium layer of the conventional photomask;

FIG. 2a schematically illustrates a cross-sectional view of a photomask product including a superior chromium-based material layer stack in order to enable the patterning of mask features with a reduced tendency of chromium diffusion, according to illustrative embodiments;

FIG. 2b schematically illustrates a graph representing the dependence of optical density on a thickness of the material layers of the layer stack of FIG. 2a, according to illustrative embodiments; and

FIGS. 2c-2e schematically illustrate cross-sectional views of a photomask during various manufacturing stages in imparting reduced probability of chromium diffusion to the corresponding mask features, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

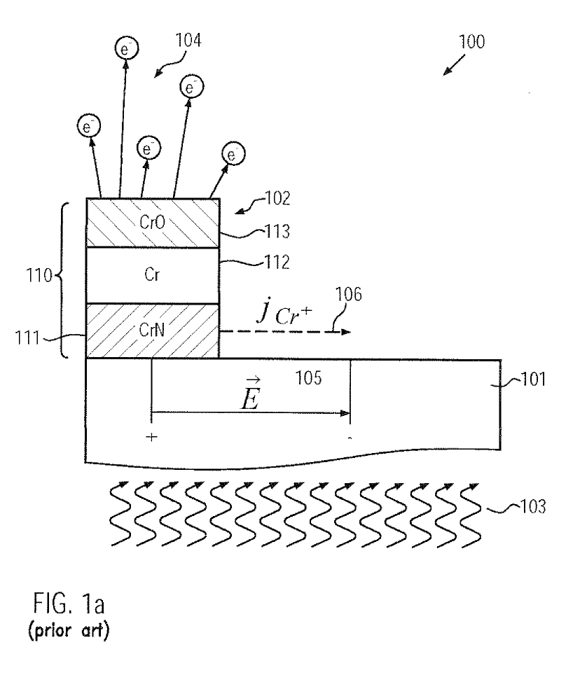

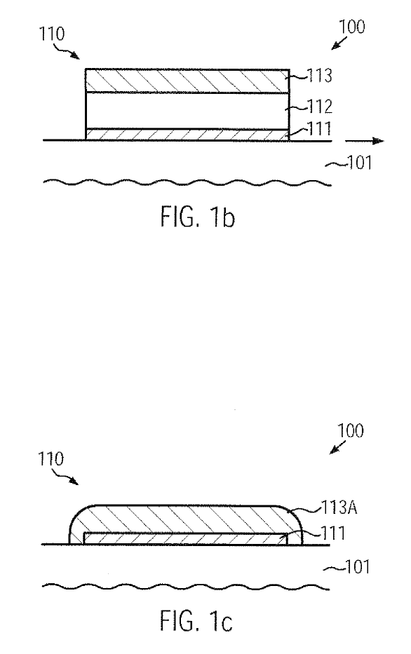

Generally, the present disclosure relates to devices and techniques in which chromium diffusion in chromium-based photomasks may be suppressed, thereby providing superior durability, thus significantly reducing production costs of sophisticated microstructure devices, such as integrated circuits and the like. As previously explained, it is believed that significant chromium diffusion may be induced for a plurality of reasons, for instance as explained before with respect to FIG. 1a. Moreover, it is also widely accepted that a rough substrate surface may enhance the surface migration. Since the substrates for forming photomasks are typically mechanically polished prior to applying chromium-based material layers, a certain degree of roughness may be present and may thus contribute to the chromium diffusion. Additionally, some of the manufacturing processes for patterning the photomask may also have an effect on the generation of substrate roughness. Moreover, it is assumed that the roughness at the sidewalls of the mask features, which may be caused by a granular-like structure of the base material, may have an influence on the finally observed chromium migration. For example, a heterogeneous sidewall surface may lead to extremely high local electric field strengths at surface features, with small radius of curvature, which in turn may promote the release of chromium ions. Consequently, in the context of the present application, investigations have been performed in order to identify further reasons for a pronounced chromium migration. Without intending to restrict the present application to the following explanation, it is believed that, based on these investigations, the conventional chromium layer may represent the main contributor to the chromium diffusion, as will be explained with reference to FIGS. 1b and 1c.

FIG. 1b schematically illustrates the photomask 100 in an initial stage of operation, wherein the feature 110 may still have its desired configuration, i.e., the layers 111, 112 and 113 may have a desired material composition, height and shape so as to act as a mask for imaging corresponding features on a carrier material of a microstructure device. During the usage of the photomask 100, a relatively high degree of chromium “depletion” of the chromium layer 112 has been observed, caused by its release from the bulk, with subsequent transformation into chromium oxide. Thereby, the optical characteristics of the mask feature 110 could be significantly altered.

FIG. 1c schematically illustrates the mask 100 in a further advanced stage of the deterioration mechanism caused by chromium migration, in which the layer 112 of FIG. 1b may have been substantially (or even completely) “consumed” and merged together with the layer 113 in FIG. 1b, thereby resulting in a modified chromium oxide layer 113A. In this particular case, the layer 113A means, but is not restricted to, a mixture of non-deteriorated 113 and degraded 112. Moreover, the material distribution 113A may be non-uniform across the lateral extension of the feature 110, which may be caused by any defects that are not yet understood. Furthermore, the thickness of the chromium nitride layer 111 may substantially remain the same throughout the entire phase of mask deterioration, thereby indicating that chromium nitride may be very stable and may substantially not contribute to the chromium migration.

Consequently, according to some illustrative embodiments disclosed herein, a photomask product and photomasks may be provided with an appropriately designed chromium-based layer stack in which a desired degree of passivation with respect to chromium diffusion may be accomplished by excluding a substantially pure chromium layer, while adjusting the desired optical characteristics of the layer stack on the basis of one or more chromium-containing material layers, which may have an enhanced stability with respect to chromium migration.

In other illustrative embodiments disclosed herein, the chromium diffusion may be efficiently reduced by passivating a layer stack of a mask feature which may contain a chromium layer by forming an appropriate diffusion barrier in order to “encapsulate” the chromium material in the mask feature. Moreover, by using a dielectric material as a diffusion barrier, any desired electrical field strengths may also be reduced. Consequently, well-established materials, such as chromium, chromium nitride and chromium oxide, may be efficiently used on the basis of well-established process techniques and process tools, while at the same time significantly reducing the degree of mask deterioration caused by chromium migration.

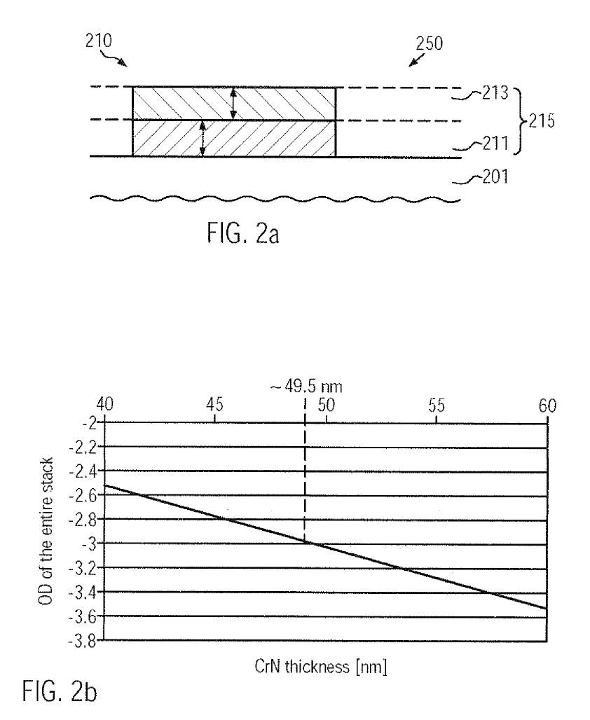

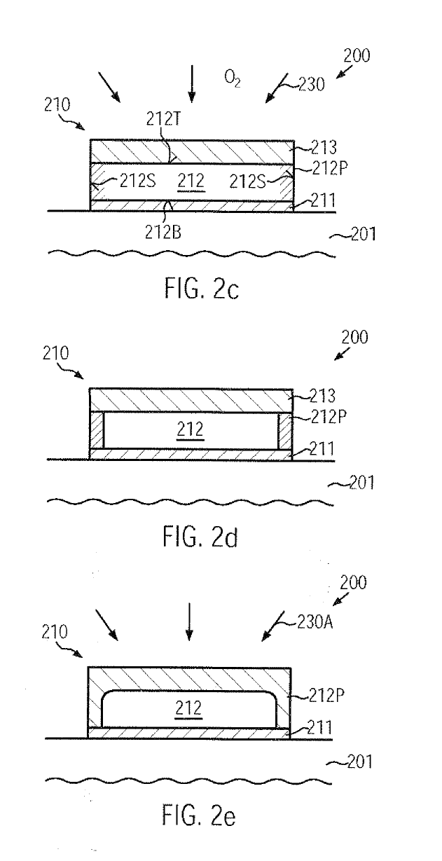

With reference to FIGS. 2a-2e, further illustrative embodiments will now be described in more detail, wherein reference may also be made to FIGS. 1a-1c, if appropriate.

FIG. 2a schematically illustrates a cross-sectional view of a photomask product 250, which is to be understood as a “blank” photomask which may comprise a transparent substrate 201, such as a quartz glass substrate and the like, in combination with a material layer stack 215, which may, upon further processing, be patterned so as to obtain mask features 210, as required for specific device levels of microstructure devices, as discussed above. The layer stack 215 may comprise a first material layer 211 formed on the substrate 201, followed by a second material layer 213 formed on the first layer 211, wherein at least one of the layers 211, 213 may comprise a chromium species. It should be appreciated that “comprising a chromium species” is to be understood as any material compound formed on the basis of chromium with a fraction of at least 10 atomic percent and at least one further non-chromium species, wherein the fraction of the at least one further non-chromium species in relation to the entire amount of the compound is approximately 10 atomic percent or higher. For example, material layers such as chromium nitride (CrN), chromium carbide (Cr₃C₂), chromium oxide (CrO) and the like are to be considered as chromium-based compounds since the fraction of both the chromium species and the non-chromium species is greater than approximately 10 atomic percent. On the other hand, any other chromium-based material layer with an amount of non-chromium species of less than 10 atomic percent may be understood as a “chromium” layer. According to previous explanations with respect to FIGS. 1b and 1c, a chromium layer may be avoided in the layer stack 215, while nevertheless providing at least one chromium-based material compound to take advantage of well-established material handling recipes, process tools and the like when patterning the layer stack 215 into the mask features 210 to provide a photomask. In one illustrative embodiment, the first material layer 211 may be provided in the form of a chromium nitride layer, which may provide superior stability with respect to chromium migration and the like. In other cases, the material layer 211 may be provided in the form of a chromium carbide material, which may also represent a highly stable material. In other cases, any other combination of materials may be used, for instance, a nitrogen and carbon-containing chromium-based layer, wherein, however, as explained above, the overall amount of nitrogen and carbon is higher than approximately 10 atomic percent. In some illustrative embodiments, the second material layer 213 may be comprised of chromium oxide, thereby providing the well-known optical characteristics of this material, wherein the overall optical characteristics of the layer stack 215, i.e., optical density, may be adjusted by appropriately selecting the thickness of the layers 211 and 213 for a given material composition thereof. For example, by providing the layer stack 215 on the basis of chromium nitride, chromium carbide and chromium oxide, well-established material sources, manufacturing techniques and process tools may be employed, thereby providing a high degree of compatibility with the processing of conventional photomask products based on the layer stack 111, 112 and 113 as previously described with reference to FIGS. 1a-1c.

In other illustrative embodiments, one of the layers of the stack 215 may be provided in the form of a substantially chromium-free material, as long as the desired optical characteristics and compatibility with available processing resources are met. For example, the layer 213 may be provided in the form of a tantalum-based material, such as tantalum nitride, which represents a frequently used material in photomask processing and semiconductor manufacturing. Consequently, appropriate process recipes for depositing and patterning a tantalum-based material layer are available and may be used for forming the layer stack 215.

The product 250 may be formed on the basis of appropriate process techniques, i.e., deposition of the individual layers 211, 213 of the layer stack 215. For example, well-established chromium-based materials, as previously explained, may be deposited on the basis of well-established process techniques, while also adjusting the desired layer thickness, as will be described later on with reference to FIG. 2b. For instance, using nitrides and carbides as the main building block for the stack 215 may be advantageous for suppressing chromium migration and may also provide additional advantages since these materials are extremely stable. For example, during the nitride deposition, a very good adhesion to the substrate 101 may be achieved, wherein, in some cases, even a slight penetration of the substrate 201 may occur. Additionally, oxidation of the nitride or carbide materials may take place at very elevated temperatures only, that is, above 700° C. (values uncommon for photomask manufacturing and its technical application), thereby endowing the layer stack 215 with superior resistivity for degradation caused by high temperatures. Furthermore, chromium nitrides and carbides may be extremely inert with respect to acids, bases, solvents, caustics and the like. Moreover, these layers fit a very low Young's modulus of, for instance, 200 GPa for chromium nitride. With respect to the Rockwell C-scale, chromium nitride is harder compared to metallic components, such as a pure chromium material. Thereafter, the material layer 213 may be deposited on the basis of any appropriate deposition technique, depending on the type of material composition. It should be appreciated that additional material layers may be provided in the layer stack 215, if considered advantageous in view of optical characteristics, patterning characteristics, stability and the like. In some illustrative embodiments, a chromium oxide may be formed with an appropriate thickness so as to obtain the desired ARC behavior and the optical density in combination with the layer 211, as will be described later on in more detail. In other cases, other materials, such as titanium nitride may be deposited, for instance, by sputter deposition and the like, wherein an internal stress level of the entire layer stack 215 may be reduced compared to conventional stacks, as described above, thereby obtaining a reduced degree of pattern placement errors. This type of imaging error describes a deviation of an actual position of an image feature with respect to its target position caused by a pattern inherent deformation. Consequently, by reducing the initial inherent stress level of the layer stack 215, the mask features 210 may be patterned with superior position accuracy while also reducing the influence of external contributions, such as thermal stress and the like, on the finally obtained positioning accuracy. Additionally, more aggressive etch chemistry may be used due to the superior chemical stability, thereby potentially ensuring higher yield while reducing the probability of negative side effects, such as haze and the like. Consequently, upon processing the product 250 into a photomask including the mask feature 210, more efficient processes may be applied. Furthermore, due to the avoidance of a “pure” chromium material, the effect of chromium migration may be suppressed or at least be significantly reduced. Consequently, based on the product 250, photomasks of the type “chrome on glass” or any binary photomasks may be produced.

FIG. 2b schematically illustrates a graph in which a dependence of the optical density of the layer stack 215 on the thickness of the layer 211 while 213 is equivalent in thickness, elemental composition and optical properties to 113 from FIG. 1b. For convenience, the mechanism illustrated in FIG. 2b refers to a layer stack including a chromium nitride material for the layer 211 and a chromium oxide material for the layer 213. Furthermore, in order to more clearly demonstrate the principle of adapting the optical characteristics, the thickness of the chromium oxide layer 213 may be selected in advance, for instance to be approximately 18 nm, and only the thickness of the chromium nitride layer 211 may be varied. In the present case, an exposure wavelength of 193 nm is selected. As is evident from FIG. 2b, an optical density of −3 may be obtained at a thickness of approximately 49.5 nm of the layer 211. Consequently, for an overall height of the layer stack 215 of approximately 70 nm, a minimum optical density of −3 may be achieved. It should be appreciated that for other material compositions of the layers 211 and 213 corresponding thickness ratios may be selected, wherein, if desired, a thickness of these layers may be varied in order to obtain the desired optical characteristics. As previously discussed, in view of the overall characteristics of the stack 215, it is advantageous to provide highly stable chromium nitride with a greater thickness compared to the chromium oxide layer.

With reference to FIGS. 2c-2e, further illustrative embodiments will now be described in which a superior behavior with respect to chromium migration may be achieved on the basis of mask features comprising a substantially “pure” chromium material.

FIG. 2c schematically illustrates a photomask 200 in an advanced stage of a process for forming the mask feature 210 on the substrate 201. As illustrated, the mask feature 210 may comprise the chromium nitride layer 211 formed on the substrate 201, followed by a chromium layer 212, while the chromium oxide layer 213 may be provided as a top layer of the feature 210. Consequently, according to this configuration of the mask feature 210, a high degree of compatibility to conventional photomasks may be obtained and thus well-established materials and process techniques can be applied to pattern the photomask 200 on the basis of corresponding conventional blank photomask products. Moreover, in this manufacturing stage, the photomask 200 may be exposed to a reactive process ambient 230 which may be configured to form a protective material at sidewalls 212S of the layer 212. In one illustrative embodiment, the reactive process ambient 230 may represent an oxidation process, in which oxygen species may be brought into contact with the exposed sidewall surface areas 212S to initiate a local oxidation, thereby forming the protection material 212P in the form of a chromium oxide material. On the other hand, a top surface 212T and a bottom surface 212B of the material 212 may be protected by the layers 213 and 211, respectively.

In one illustrative embodiment, the reactive process ambient 230 may be established on the basis of a plasma, which may be created in a plasma etch tool or a plasma deposition tool, wherein oxygen may be introduced, in combination with any inert gas species, such as argon, helium and the like. Furthermore, appropriate pressure conditions and desired bias power may be established to obtain a slight degree of ion bombardment even at the substantial vertical sidewalls 212S. Consequently, during the plasma assisted process, a chromium oxide layer, i.e., a CrₓO₁₋ₓ layer, will be formed at the sidewalls 212S, thereby forming the protection material 212P. In this manner, the chromium material 212 may be encapsulated, while at the same time a dielectric enclosure of the material 212 may be accomplished, thereby also reducing the effect of any electric field that may build up during processing and handling of the mask 200, as is explained before. It should be appreciated that appropriate process parameters for a plasma treatment may be readily established on the basis of experiments, for instance, by selecting an appropriate high frequency power for establishing the plasma ambient and also adjusting a desired bias power in combination with appropriate gas flow rates for oxygen and the inert gas component.

In other illustrative embodiments, the reactive process ambient 230 may be established as an oxidation process by using a wet chemical etch chemistry, as may also be frequently applied when performing a cleaning process. For instance, any solutions including hydrogen peroxide may be efficiently used, for instance in combination with sulfuric acid and the like. Consequently, also in this case, a thin layer of the protection material 212P may be efficiently formed on the exposed sidewall faces 212S. On the other hand, the high stability of the material 211 may substantially prevent any significant modification of exposed areas of the layer 211, while also the material 213 may not be significantly affected by the process 230.

In other illustrative embodiments, the process 230 may represent a plasma assisted process for incorporating other species, such as nitrogen, carbon and the like, into exposed surface areas of the feature 210. Also in this case, appropriate plasma conditions may be established to create an overall “isotropic” plasma with a mild ion bombardment, thereby also efficiently incorporating the desired species into the surface areas 212S. In this case, the protection material 212P may represent a mixture of chromium and a further species, wherein, at least at a surface area, a significant enrichment may be achieved so that a fraction of approximately more than 10 atomic percent of the non-chromium species may be obtained, thereby imparting the desired diffusion blocking characteristics to the material 212P.

FIG. 2d schematically illustrates the photomask 200 after the process 230. As illustrated, the chromium material 212 may be encapsulated by the layers 211 and 213 and by the protection material 212P, which may have a thickness of one to several nanometers, depending on the process conditions during the preceding treatment 230 of FIG. 2c. For example, providing the material 212P in the form of chromium oxide, wherein the exact stoichiometric formula may depend on the process conditions, may provide high diffusion barrier effects and may also act as a dielectric material. In other cases, the protection material may, in addition or alternatively to, oxygen comprise other species, such as nitrogen, carbon and the like, thereby even further enhancing the overall stability of the protection material 212P. It should be appreciated that the formation of the protection material 212P on the basis of the treatment 230 of FIG. 2c may not result in a significant modification of the geometry of the mask feature 210, since only the surface of the feature 210 may take part in the corresponding process. Consequently, the critical dimension and hence any OPC features may not be substantially affected by providing the protection material 212P. Therefore, the material 212P may be formed by an additional production step with respect to conventional process strategies without requiring significant efforts of product requalification upon using the photomask 200. Consequently, a high degree of compatibility with conventional process strategies and process resources may be accomplished while nevertheless providing superior lifetime of the photomask 200 due to a significant reduction in chromium migration.

FIG. 2e schematically illustrates the photomask 200 according to further illustrative embodiments in which the mask feature 210 may be patterned on the basis of a layer stack comprising the layer 211 and the chromium layer 212. For this purpose any well-established patterning strategies may be applied. Thereafter, the photomask 200 may be exposed to a reactive ambient 230A, such as an oxidizing ambient, in which a portion of the material 212 may be converted into the protection material 212P, thereby encapsulating the remaining portion of the material 212. In this case, the process 230A may be controlled so as to obtain a desired thickness of the protection material 212P above the material 212 to act as an efficient ARC layer, while at the same time protect the sidewalls of the material 212. Consequently, a simplified material stack may be used for patterning the mask feature 210, thereby contributing to a superior process flow.

As a result, the present invention provides lithography mask products, photomasks and manufacturing techniques in which chromium migration may be suppressed or at least significantly reduced by avoiding substantially pure chromium materials and/or by appropriately encapsulating the chromium material. Consequently, photomasks of superior variability and stability may be provided on the basis of well-established chromium-based materials, wherein, in some illustrative embodiments, a high degree of compatibility with conventional materials and process techniques may be maintained.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A photolithography mask product, comprising:
a transparent substrate; and
a material layer stack formed on said transparent substrate, said material layer stack comprising a first material layer formed on said substrate and a second material layer formed on said first material layer, said first material layer comprising a chromium-containing compound, said second material layer comprising at least one non-chromium species with a fraction of approximately 10 atomic percent or more.

2. The photolithography mask product of claim 1, wherein said chromium-containing compound of said first material layer comprises nitrogen.

3. The photolithography mask product of claim 1, wherein said chromium-containing compound of said first material layer comprises carbon.

4. The photolithography mask product of claim 1, wherein said at least one non-chromium species of said second material layer comprises oxygen.

5. The photolithography mask product of claim 4, wherein said second material layer comprises chromium oxide.

6. The photolithography mask product of claim 5, wherein said first material layer comprises at least one of chromium nitride and chromium carbide and wherein said second material layer is a chromium oxide layer.

7. The photolithography mask product of claim 6, wherein a height of said material layer stack is approximately 100 nm or less.

8. The photolithography mask product of claim 1, wherein said at least one non-chromium species of said second material layer comprises at least one of tantalum and nitrogen.

9. The photolithography mask product of claim 8, wherein said second material layer comprises tantalum nitride.

10. The photolithography mask product of claim 1, further comprising a mask feature comprising said first and second material layers.

11. A photolithography mask, comprising:
a transparent substrate; and
an opaque mask feature formed on said transparent substrate, said opaque mask feature comprising a chromium layer formed above said transparent substrate, said chromium layer having a bottom face and a top face and sidewall faces, said opaque mask feature comprising a sidewall protection material formed on each of said sidewall faces, a composition of said sidewall protection material differing from a composition of said chromium layer.

12. The photolithography mask of claim 11, wherein said mask feature further comprises a bottom material layer formed on said transparent substrate so as to connect to said chromium layer.

13. The photolithography mask of claim 12, wherein said mask feature further comprises a top material layer formed on said chromium layer.

14. The photolithography mask of claim 11, wherein said sidewall protection material comprises chromium oxide.

15. The photolithography mask of claim 11, wherein said sidewall protection material comprises chromium nitride.

16. The photolithography mask of claim 13, wherein said bottom material layer and said top material layer comprise chromium.

17. A method of forming a photolithography mask, the method comprising:
patterning a material layer stack formed on a transparent substrate to form a mask feature, said material layer stack comprising at least one chromium-containing material layer; and
passivating said mask feature to reduce chromium diffusion.

18. The method of claim 17, wherein passivating said mask feature comprises forming at least one of a diffusion barrier and a dielectric layer on sidewalls of said mask feature.

19. The method of claim 18, wherein forming said at least one of a diffusion barrier and a dielectric layer comprises performing an oxidation process to oxidize an oxidizable portion of said sidewalls.

20. The method of claim 19, wherein performing said oxidation process comprises performing a plasma assisted oxidation process.

21. The method of claim 19, wherein performing said oxidation process comprises performing a wet chemical oxidation process.

22. The method of claim 19, wherein performing said oxidation process comprises oxidizing a top surface of said material stack.

23. The method of claim 18, wherein forming said diffusion barrier layer comprises performing a plasma treatment to incorporate at least one of nitrogen and carbon in at least a portion of said sidewalls.

24. The method of claim 17, wherein passivating said mask feature comprises providing said at least one chromium-containing layer in the form of a chromium compound layer.

25. The method of claim 24, wherein said chromium compound layer is provided as at least one of a chromium nitride layer, a chromium carbide layer and a chromium oxide layer.
